(19) United States
(12) Patent Application Publication
(10) Pub. No.: US 2014/0146601 A1
(43) Pub. Date: May 29, 2014

(54) PROCESSORS AND SYSTEMS WITH MULTIPLE REFERENCE COLUMNS IN MULTIBIT PHASE-CHANGE MEMORY

(71) Applicant: Being Advanced Memory Corporation, (US)

(72) Inventor: Aaron D. Willey, Burlington, VT (US)

(73) Assignee: Being Advanced Memory Corporation, Essex Junction, VT (US)

(21) Appl. No.: 13/869,679

(22) Filed: Apr. 24, 2013

Related U.S. Application Data
(60) Provisional application No. 61/694,223, filed on Aug. 28, 2012.
(60) Provisional application No. 61/694,224, filed on Aug. 28, 2012.
(60) Provisional application No. 61/694,225, filed on Aug. 28, 2012.

(51) Int. Cl. G11C 13/00

(52) U.S. Cl. CPC G11C 13/0069
USPC 365/163

(57) ABSTRACT

Systems and devices in which multi-bit phase change memory is used, including memory systems and memories, as well as methods for operating such systems and devices. According to the present invention, a reference corresponding to a pair of adjacent logical states (e.g., 0 and 1) can be generated by averaging outputs from multiple phase change memory reference cells designated to store said adjacent logical states. By writing reference cells contemporaneously with words of cells that are configured to be written together, resulting references can closely track output changes in corresponding ones of said words resulting from, e.g., drift and other time- and phase change material-dependent factors. Ordering of states within said reference cells can be used to encode information such as checksums of corresponding words.

### CROSS-REFERENCE

Priority is claimed from U.S. Provisional Patent Applications 61/694,223, 61/694,224, and 61/694,225, all filed Aug. 28, 2012, and all hereby incorporated by reference.

### BACKGROUND

The present application relates to systems, devices and methods for memory access operations involving multi-bit phase change memory units.

Note that the points discussed below may reflect the hindsight gained from the disclosed inventions, and are not necessarily admitted to be prior art.

Phase change memory (“PCM”) is a relatively new nonvolatile memory technology, which is very different from any other kind of nonvolatile memory. First, the fundamental principles of operation, at the smallest scale, are different: no other kind of solid-state memory uses a reversible PHYSICAL change to store data. Second, in order to achieve that permanent physical change, an array of PCM cells has to allow read, set, and reset operations which are all very different from each other. The electrical requirements of the read, set, and reset operations make the peripheral circuit operations of a PCM very different from those of other nonvolatile memories. Obviously some functions, such address decoding and bus interface, can be the same; but the closest-in parts of the periphery, which perform set, reset, and read operations on an array or subarray, must satisfy some unique requirements.

The physical state of a PCM cell's memory material is detected as resistance. For each selected cell, its bitline is set to a known voltage, and the cell's access transistor is turned on (by the appropriate wordline). If the cell is in its low-resistance state, it will sink a significant current from the bit line; if it is not, it will not.

Set and Reset operations are more complicated. Both involve heat. As discussed below, a “set” operation induces the memory material to recrystallize into its low-resistance (polycrystalline) state; a “reset” operation anneals the memory material into its high-resistance (amorphous) state.

Write operations (Set and Reset) normally have more time budget than read operations. In read mode a commercial PCM memory should be competitive with the access speed (and latency if possible) of a standard DRAM. If this degree of read speed can be achieved, PCM becomes very attractive for many applications.

The phase change material is typically a chalcogenide glass, using amorphous and crystalline (or polycrystalline) phase states to represent bit states.

A complete PCM cell can include, for example: a top electrode (connected to the bit line), a phase change material (e.g. a chalcogenide glass), a conductive pillar which reaches down from the bottom of the phase change material, an access transistor (gated by a word line), and a bottom connection to ground. The phase change material can extend over multiple cells (or over the whole array), but the access transistors are laterally isolated from each other by a dielectric.

FIG. 2A shows an example of a PCM element 2010. A top electrode 2020 overlies a phase change material 2030, e.g. a chalcogenide glass. Note that material 2030 also includes a mushroom-shaped annealed zone (portion) 2070 within it. (The annealed zone 2070 may or may not be present, depending on what data has been stored in this particular location.) The annealed zone 2070, if present, has a much higher resistivity than the other (crystalline or polycrystalline) parts of the material 2030.

A conductive pillar 2050 connects the material 2030 to a bottom electrode 2040. In this example, no selection device is shown; in practice, an access transistor would normally be connected in series with the phase change material. The pillar 2050 is embedded in an insulator layer 2060.

When voltage is applied between the top 2020 and bottom 2040 electrodes, the voltage drop will appear across the high-resistivity zone 2070 (if present). If sufficient voltage is applied, breakdown will occur across the high-resistivity zone. In this state the material will become very conductive, with large populations of mobile carriers. The material will therefore pass current, and current crowding can occur near the top of the pillar 2050. The voltage which initiates this conduction is referred to as the “snapback” voltage, and FIG. 2C shows why.

FIG. 2C shows an example of instantaneous I-V curves for a device like that of FIG. 2A, in two different states. Three zones of operation are marked.

In the zone 2200 marked “READ,” the device will act either as a resistor or as an open (perhaps with some leakage). A small applied voltage will result in a state-dependent difference in current, which can be detected.

However, the curve with open circles, corresponding to the amorphous state of the device, shows some more complex behaviors. The two curves show behaviors under conditions of higher voltage and higher current.

If the voltage reaches the threshold voltage Vₜₕ, current increases dramatically without any increase in voltage. (This occurs when breakdown occurs, so the phase-change material suddenly has a large population of mobile carriers.) Further increases in applied voltage above Vₜₕ result in further increases in current; note that this upper branch of the curve with hollow circles shows a lower resistance than the curve with solid squares.

If the applied voltage is stepped up to reach the zone 2150, the behavior of the cell is now independent of its previous state.

When relatively large currents are applied, localized heating will occur at the top of the pillar 2050, due to the relatively high current density. Current densities with typical dimensions can be in the range of tens of millions of Amperes per square cm. This is enough to produce significant localized heating within the phase-change material.

This localized heating is used to change the state of the phase-change material, as shown in FIG. 2B. If maximum current is applied in a very brief pulse 2100 and then abruptly stopped, the material will tend to quench into an amorphous high-resistivity condition; if the phase-change material is cooled more gradually and/or not heated as high as zone 2150, the material can recrystallize into a low-resistivity condition. Conversion to the high-resistance state is normally referred to as “Reset”, and conversion to the low-resistance state is normally referred to as “Set” (operation 2080). Note that, in this example, the Set pulse has a tail where current is reduced fairly gradually, but the Reset pulse does not. The duration of the Set pulse is also much longer than that of the Reset pulse, e.g. tens of microseconds versus hundreds of nanoseconds.

FIG. 2D shows an example of temperature versus resistivity for various PCM materials. It can be seen that each curve has a notable resistivity drop 2210 at some particular temperature. These resistivity drops correspond to phase change to a crystalline (or polysilicon) state. If the material is cooled gradually, it remains in the low resistivity state after cooling.

In a single-bit PCM, as described above, only two phases are distinguished: either the cell does or does not have a significant high-resistivity “mushroom cap” 2070. However, it is also possible to distinguish between different states of the mushroom cap 2070, and thereby store more than one bit per cell.

FIG. 2E shows an equivalent circuit for an “upside down” PCM cell 2010. In this example the pass transistor 2240 is gated by Wordline 2230, and is connected between the phase-change material 2250 and the bitline 2220. (Instead, it is somewhat preferable to connect this transistor between ground and the phase-change material.

FIG. 2F shows another example of a PCM cell 2010. A bitline 2220 is connected to the top electrode 2020 of the phase-change material 2250, and transistor 2240 which is connected to the bottom electrode 2030 of the PCM element. (The wordline 2230 which gates the vertical transistor 2240 is not shown in this drawing.) Lines 2232, which are shown as separate (and would be in a diode array), may instead be a continuous sheet, and provide the ground connection.

FIG. 2G shows an example of resistance (R) over time (t) for a single PCM cell following a single PCM write event at time t=0. The resistance curve 2400 for a cell which has been reset (i.e. which is in its high-resistance state) may rise at first, but then drifts significantly lower. The resistance curve 2410 for a cell in the Set state is much flatter. The sense margin 2420, i.e., the difference between set and reset resistances, also decreases over time. Larger sense margins generally result in more reliable reads, and a sense margin which is too small may not permit reliable reading at all. 2G represents the approximate behavior of one known PCM material; other PCM material compositions may behave differently. For example, other PCM material compositions may display variation of the set resistance over time.

The downwards drift of reset resistance may be due to, for example, shrinking size of the amorphous zone of the phase-change material, due to crystal growth; and, in some cells, spontaneous nucleation steepening the drift curve (possibly only slightly) due to introducing further conductive elements into the mushroom-shaped programmable region.

FIG. 2H shows an example of a processing system 2300. Typically, a processing system 2300 will incorporate at least some of interconnected power supplies 2310, processor units 2320 performing processing functions, memory units 2330 supplying stored data and instructions, and I/O units 2340 controlling communications internally and with external devices 2350.

FIG. 2I shows an example of a PCM single ended sensing memory. Two different PCM cells 2400 on different ends of a sense amplifier can be selected separately. Selected elements 2410 are separately sensed by a single-ended sense amplifier 2420.

FIG. 2J shows an example of a known PCM single ended sense amplifier 2500. Generally, in a single ended sense amplifier, a cell read output conducted by a selected bitline BLB is compared against a reference current to provide a digital output OUT. When the PRECHARGE signal turns on transistor 2530, voltage V04 (e.g., 400 mV) precharges the bitline BLB. After precharge ends, the READ signal turns on transistor 2550. Transistor 2550 is connected, through source follower 2560 and load 2580, to provide a voltage which comparator 2600 compares to Voltage_REF, to thereby generate the digital output OUT.

A variety of nonvolatile memory technologies have been proposed over recent decades, and many of them have required some engineering to provide reference values for sensing. However, the requirements and constraints of phase-change memory are fundamentally different from those of any other kind of nonvolatile memory. Many memory technologies (such as EEPROM, EPROM, MNOS, and flash) test the threshold voltage of the transistor in a selected cell, so referencing must allow for the transistor's behavior. By contrast, phase-change memory simply senses the resistance of the selected cell. This avoids the complexities of providing a reference which will distinguish two (or more) possibilities for an active device's state, but does require detecting a resistance value, and tracking external variations (e.g. temperature and supply voltage) which may affect the instantaneous value of that resistance.

The possibility of storing more than one bit of data in a single phase-change material has also been suggested. Phase-change memories implementing such architectures are referred to here as “multibit” PCMs. If the “Set” and/or “Reset” operations can be controlled to produce multiple electrically distinguishable states, then more than one bit of information can be stored in each phase-change material location. It is known that the current over time profile of the Set operation can be controlled to produce electrically distinguishable results, though this can be due to more than one effect. In the simplest implementation, shorter anneals—too short to produce full annealing of the amorphous layer—can be used to produce one or more intermediate states. In some materials, different crystalline phases can also be produced by appropriate selection of the current over time profile. However, what is important for the present application is merely that electrically distinguishable states can be produced.

For example, if the complete layer of phase-change material can have four possible I/V characteristics, two bits of information can be stored in each cell—IF the read cycle can accurately distinguish among the four different states.

(The I/V characteristics of the cells which are not in the fully Set state are typically nonlinear, so it is more accurate to distinguish the states in terms of current flow at a given voltage; resistance is often used as a shorthand term, but implies a linearity which may not be present.)

In order to make use of the possible multibit cell structures, it is necessary to reliably distinguish among the possible states. To make this distinction reliably, there must be some margin of safety, despite the change in characteristics which may occur due to history, manufacturing tolerances, and environmental factors. Thus the read architecture of multibit PCMs is a far more difficult challenge it is for PCMs with single-bit cells.

### SUMMARY

The present application discloses surprising new approaches to multibit phase-change memory (PCM) arrays, subarrays, modules, chips, components, and systems, as well as methods for making and using these. When a multibit cell on a given wordline is accessed, multiple reference values are generated using the outputs of multiple multi-bit PCM reference cells which are located in reference columns, and gated by the same wordline. The reference cells preferably include one cell with each of the possible data states; the average of two adjacent data states will therefore provide a precise reference for distinguishing those two states. Since the reference cells will closely track variation and history of the multi-bit PCM data cells on the same wordline, the derived reference values will track any variations due to manufacturing, environment, and history.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1A shows an example of a multi-bit PCM memory.

FIG. 1B shows an example of logical states stored in a multi-bit PCM memory.

FIG. 1C shows an example of a multi-bit PCM memory.

FIG. 2A shows an example of a PCM element.

FIG. 2B shows an example of PCM bit line signals.

FIG. 2C shows an example of voltage versus current in a PCM material.

FIG. 2D shows an example of temperature versus resistance in a PCM material.

FIG. 2E shows an example of a PCM cell.

FIG. 2F shows an example of a PCM cell.

FIG. 2G shows an example of resistance over time for a PCM cell.

FIG. 2H shows an example of a processing system.

FIG. 2I shows an example of a PCM single ended sensing memory.

FIG. 2J shows an example of a known PCM single ended sense amplifier.

FIG. 3 shows an example of a multi-bit PCM memory.

FIG. 4 shows an example of a multi-bit PCM memory.

FIG. 5 shows an example of a sense amplifier.

FIG. 6A shows an example of a multi-bit PCM memory.

FIG. 6B shows an example of logical states stored in a multi-bit PCM memory.

FIG. 7 shows an example of a processing system.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The present application discloses ered a way to make a novel phase change memory cell reference, generally entirely overcoming the need for coarse trimming. The reference comprises a boundary, or switchover point, between adjacent logical values; for example, whether a multi-bit PCM cell read output will be discriminated by a sense amplifier as a “0” or as a “1”. By using multiple multi-bit PCM cells (“reference cells”) storing all possible logical states for the particular multi-bit PCM (for example, “0”, “1” and “2” for a three-state PCM), applying the same voltage across a pair of multi-bit PCM cells storing adjacent logical states, and using some ratio of the total current generated as a reference, the reference can be reliably matched to other multi-bit PCM cells in the memory.

Multi-bit PCM materials generally exhibit an inherent “resistance drift” associated with each storage cell. Typically, drift increases during service at a predictable time-dependent rate characteristic of a corresponding multi-bit PCM material, with the drift versus time curve starting from (t=0) when a multi-bit PCM phase change (e.g., a write) occurs. By writing reference cells contemporaneously with a corresponding word of multi-bit PCM memory, drift characteristics of the reference cells can be matched to drift characteristics of the co-written storage cells.

The cells used to generate the reference track the resistance drift and resistance temperature response characteristics of cells in a corresponding word. Therefore, the generated reference can be guaranteed to be between actual multi-bit PCM cell outputs corresponding to adjacent logical states from cells in the corresponding word. Because outputs from the corresponding word that correspond to a “0” logical state will always fall on one side of the reference, and outputs from the corresponding word that correspond to a “1” state will always fall on the other side of the reference, the reference can be used to reliably distinguish between “0” and “1” (and other logical state) outputs.

If multi-bit PCM read output values are viewed as currents, then for a cell pcmₖ having some data state which provides a non-minimal output I_{pcm(k)}, consider another cell pcm₍ⱼ₎ whose data state corresponds to the next lower possible value I_{pcm(j)} of current output. To distinguish the output currents of these two states, a reference current I_{Reference} must obey the inequality

I_{pcm(j)}<I_{Reference}<I_{pcm(k)}

(or, with the opposite relation, I_{pcm(k)}<I_{Reference}<I_{pcm(j)}).
Margins between I_{pcm(j)} and I_{Reference}, and between I_{Reference} and I_{pcm(k)}, can be targeted to optimize read quality (e.g., reliability).

For example, a reference for discriminating adjacent states j and k can be generated by taking a simple average of adjacent current values I_{pcm(j)} and I_{pcm(k)} from a single pair of reference cells which are know to have been written with those states.

Alternatively, a weighted average can also be used as a reference. A weighted average can be used, for example, to compensate for greater drift or more sensitive temperature response in one PCM state than in another.

In some embodiments, multiple pairs of reference cells are used in order to obtain a more accurate result, preferably with the same voltage across all reference cells used to generate a single reference. As the number of reference cell pairs increases, reference accuracy increases. In this case, a reference is generated by taking a ratio (e.g., a weighted or unweighted average) of the summed outputs of corresponding reference cells.

In multi-bit memory, pairs of adjacent logical states are used to generate a reference. For example, for a memory using four (4) state multi-bit PCM cells (states “0”, “1”, “2”, and “3”), references would be generated from averages of outputs from cells with states “0” and “1”, states “1” and “2”, and states “2” and “3”. Generally, for n state multi-bit PCM cells, n−1 references are required to discriminate the n logical states.

The n adjacent reference cells used to generate references for n-bit PCM should be monotonically ordered; that is, a most-crystalline state should not be paired and used to generate a reference with a most-amorphous state when there are intermediate phase states (corresponding to intermediate logical states) interposed between them. This means that the corresponding averaged reference currents will also be monotically ordered, whether or not a weighted average is used.

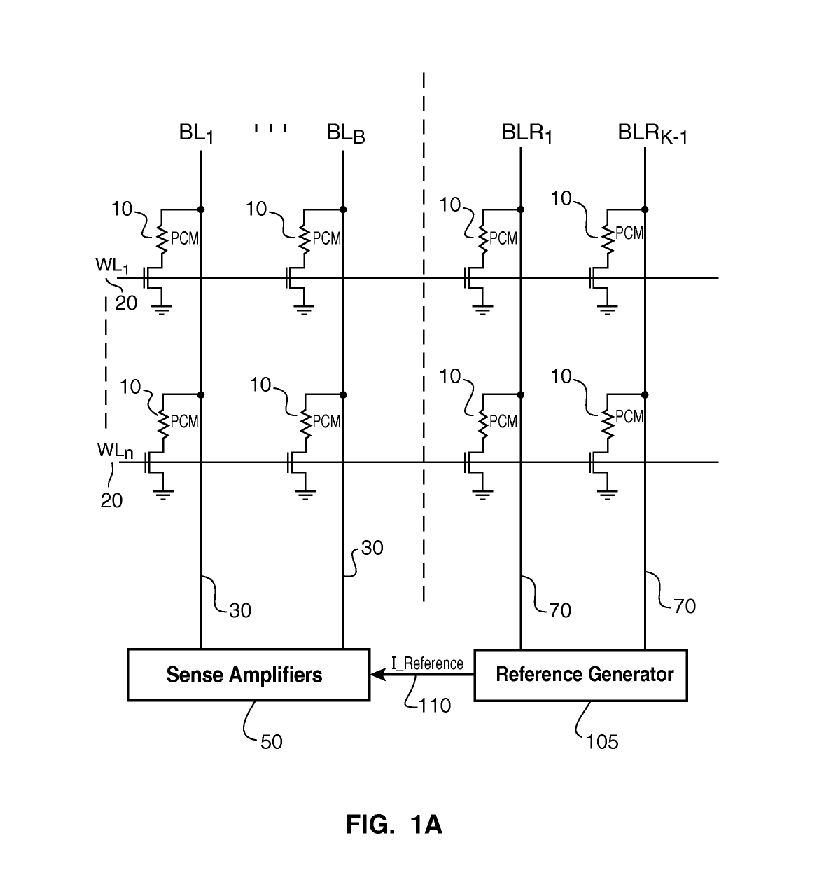

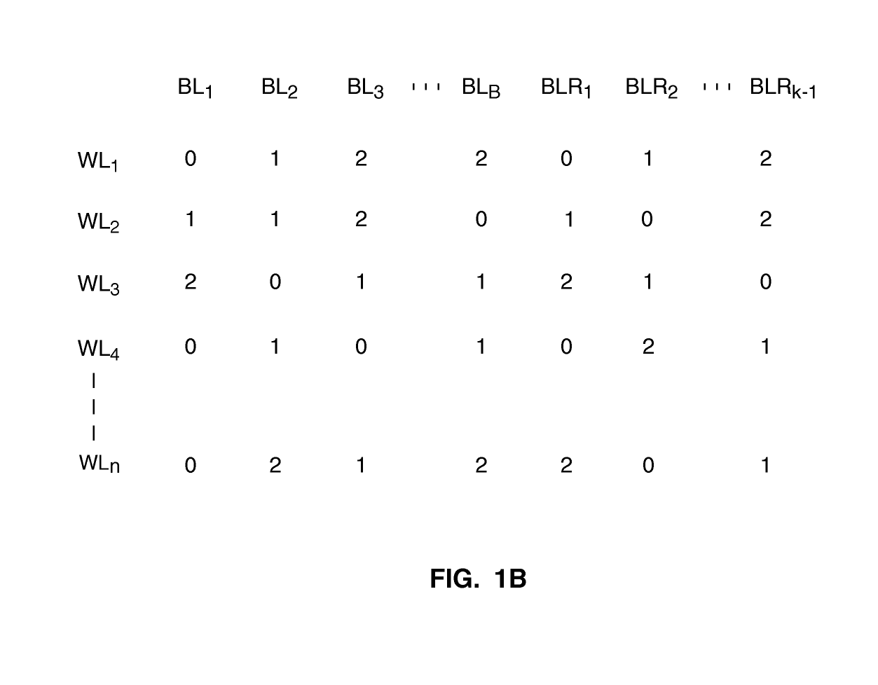

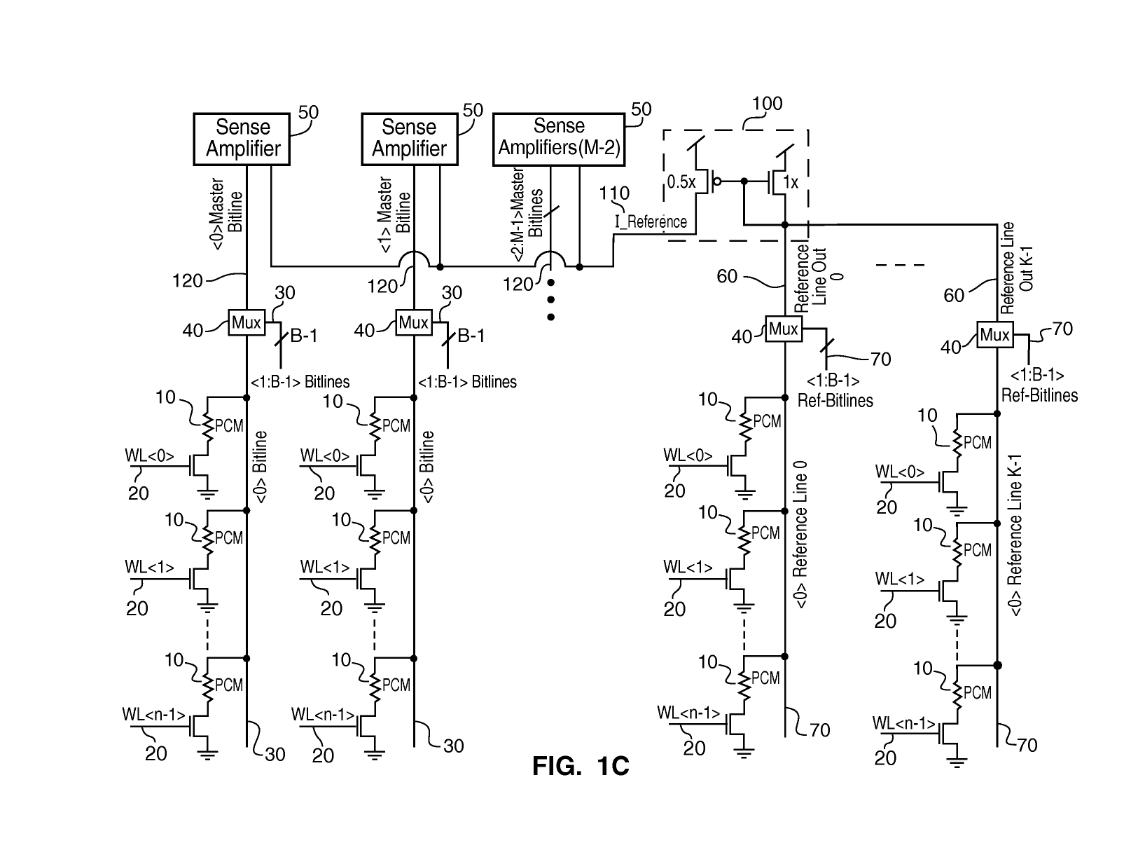

FIG. 1A shows an example of a multi-bit PCM memory. In embodiments as shown in FIG. 1A, multi-bit PCM cells 10 are accessed by n wordlines 20 (numbered WL₁ to WLₙ), B data-storing bitlines 30 (numbered BL₁ to BL_{B}) and k reference bitlines 70 (BLR₁ to BLRₖ₋₁). In FIG. 1A, a word is accessed by a wordline 20 and bitlines 30 BL₁ to BL_{B}. A multi-bit PCM cell 10 is accessed by activating the corresponding wordline 20 and bitline 30. The data-storing bitlines 30 are sensed by Sense Amplifiers 50 using references 110 (I_Reference) generated by a Reference Generator 105. When a word is read by activating a wordline 20—for example, WL₁—and multiple corresponding data-storing bitlines 30, BLR₁ to BLRₖ₋₁ are also activated. Outputs of the reference cells 10 activated by WL₁ and BLR₁ to BLRₖ₋₁, corresponding to pairs of adjacent logical states, are used by the Reference Generator 105 to generate references 110 corresponding to the respective pairs of logical states. The references 110 are then used to read the outputs of the data-storing cells 10 activated by WL₁ and BL₁ through BLₙ.

Also, when a word of data-storing cells 10 corresponding to a wordline 20 WLₖ are written, the reference cells 10 accessed by WLₖ and BLR₁ to BLRₖ₋₁ are written with at least one of each possible different logical state (e.g., “0”, “1” and “2” for a three-state PCM), so that the reference cells 10 approximately perfectly track the drift characteristics of the corresponding data-storing word.

FIG. 1B shows an example of logical states stored in a multi-bit PCM memory. Multi-bit PCM cells 10 storing logical states (in the example shown, “0”s, “1”s and “2”s) are accessed by corresponding wordlines 20 (WL₁ though WLₙ) and bitlines 30 (BL₁ through BL_{B}), and are interpreted using a reference 110 generated using outputs of reference cells 10 accessed by reference bitlines 70 (BLR₁ to BLRₖ₋₁).

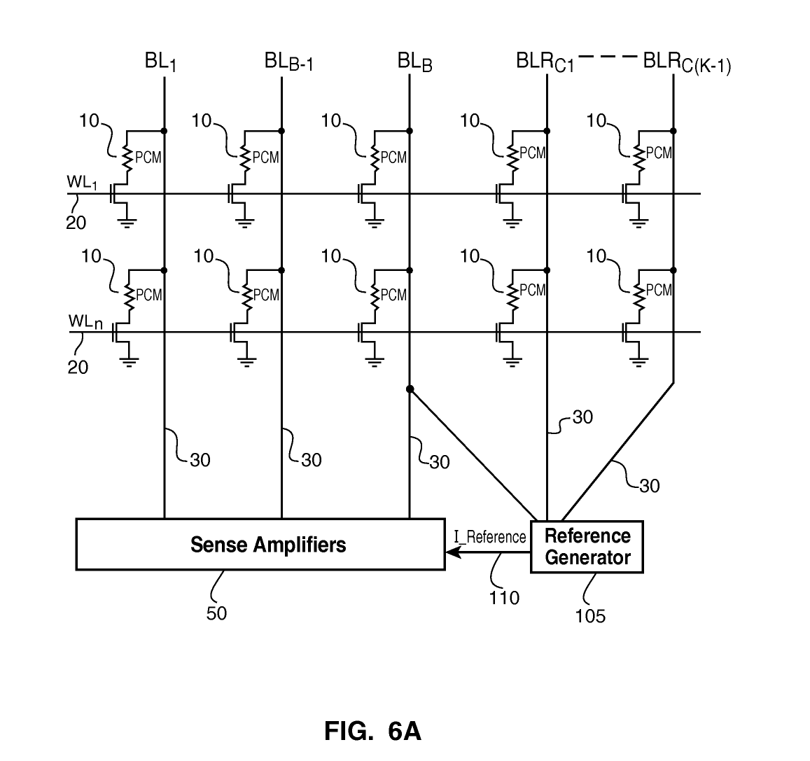

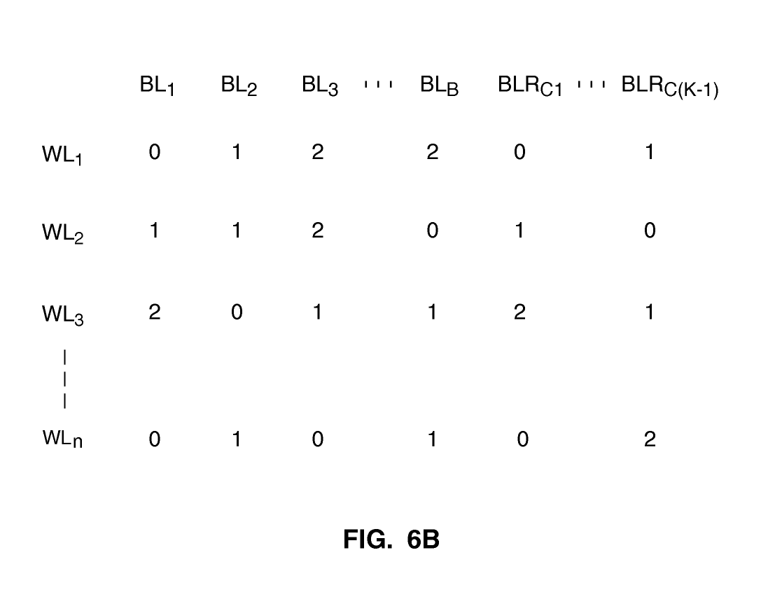

FIG. 1C shows an example of a multi-bit PCM memory. In embodiments as shown in FIG. 1C and FIG. 6C, n equals (only for FIGS. 1C and 6C) the number of multi-bit PCM cells 10 accessible by a given bitline 20, 60 and the number of wordlines 30 accessing said cells 10 (numbered 0 to n−1); B equals the number of bitlines 30 multiplexed (muxed) by a single multiplexer 40 (mux) and, for data-storing (non-reference) bitlines 20, sensed by a given sense amplifier 50 (numbered 0 to B−1); and M is the number of sense amplifiers 50 and also the number of muxes 40 configured to mux bitlines 30 accessing data-storing (non-reference) cells 10 (numbered 0 to M−1). Mux 40 outputs correspond to outputs of accessed cells 10. Wordlines 20 WL<index-n> and bitlines 30 <index-B>Bitline access corresponding multi-bit PCM cells 10.

For a k-state PCM, there are also (generally at least) k Reference Lines Out (numbered 0 to k−1) 60, comprising the output of muxes 40 that mux reference bitlines 70 accessing cells 10 storing k logical states (<index-B>Reference Lines 0 to k−1) 70. The reference cells 10 corresponding to the Reference Lines 60 are read and written with corresponding words of data-storing cells 10.

When data-storing cells 10 in a word are accessed by activating corresponding wordlines 20 and bitlines 30, reference cells 10 corresponding to said word on the Reference Bitlines 70 are also accessed. Pairs of accessed reference cells 10 corresponding to adjacent logical states are summed together and averaged by a current multiplier 100 to produce a reference I_Reference 110 for each pair of adjacent logical states. The references 110 are used by the sense amplifiers to interpret <0:M−1>Master Bitline 120 signals—i.e., mux outputs—into corresponding logical states stored by the accessed cells 10. Master Bitline 120 signals are mux 40 outputs corresponding to outputs from accessed cells 10.

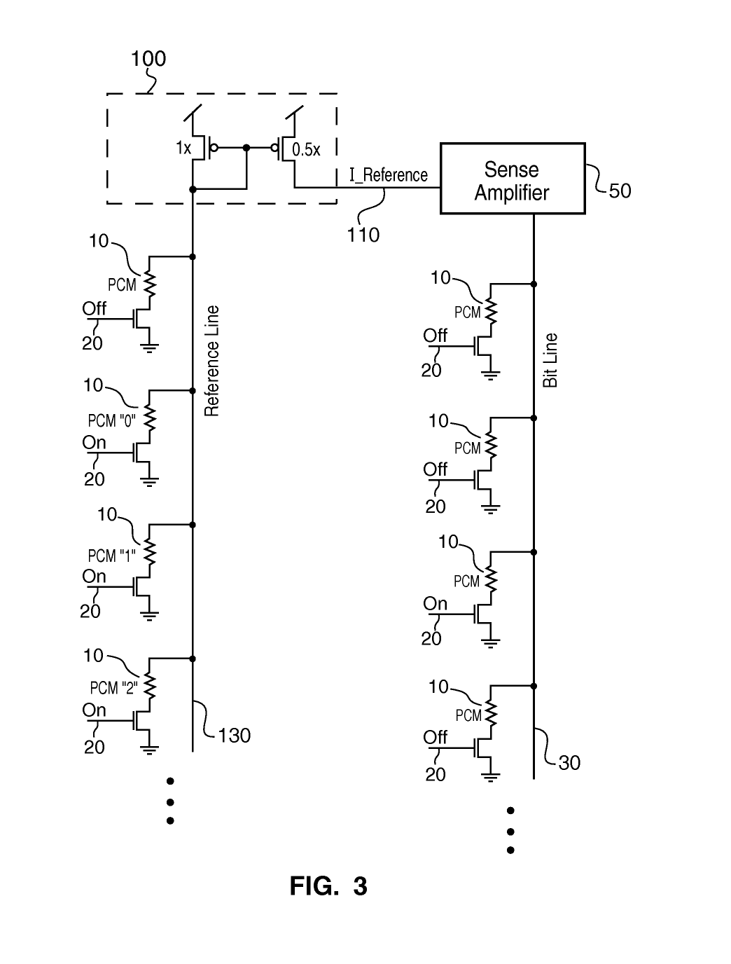

FIG. 3 shows an example of a PCM memory. Here, a mult-bit PCM reference cell 10 storing a “0” logical state 10 and a PCM reference cell 10 storing a “1” logical state are located on a single reference bitline 130 (“Reference Line”), and are accessed by turning their corresponding wordlines 20 and the Reference Line 130 “On”. The output currents from the paired reference cells 10 are averaged by a current multiplier 100 with a ratio of 0.5 (½), and the resulting reference current 110 (“I_Reference”) is fed into a sense amplifier 50 configured to sense a corresponding bitline 30. I_Reference 110 for this case can be calculated as shown in Equation 1.

On a bitline 30 comprising data-storing cells, a mult-bit PCM cell 10 that is part of a word written contemporaneously with corresponding reference cells 10 is also accessed by turning its wordline 20 and bitline 30 “On”. The resulting output current is compared by the Sense Amplifier 50 to I_Reference 110 for each possible adjacent pair of logical states. If the data-storing cell 10 output current is higher or lower than an I_Reference 110, then the data-storing cell 110 is detected to not be storing, respectively, the lower- or higher-resistance logical state referenced by that I_Reference 110.

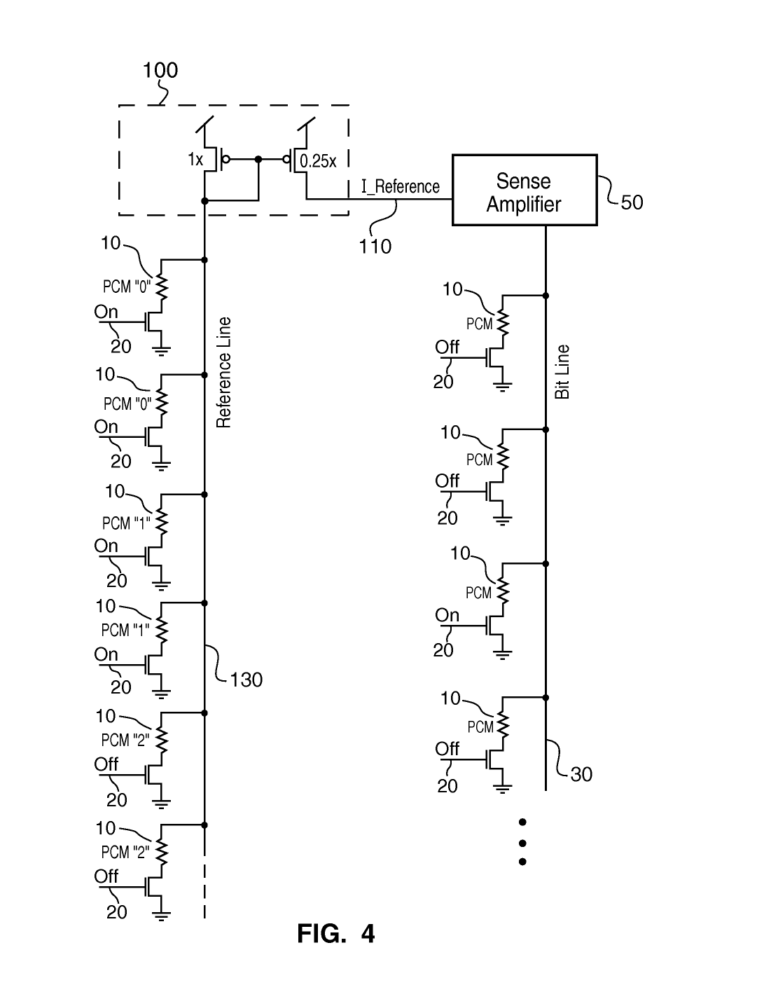

FIG. 4 shows an example of a PCM memory. Here, two pairs of cells in two groups of reference cells 10 storing adjacent logical states (“0” and “1”), each group storing all three possible states of a three-state PCM, are accessed by activating their corresponding wordlines 20 and Reference Line 130, and their output currents are summed—they are connected to the same Reference Line 130—and the resulting current is averaged by the current multiplier 100. As shown, because four reference cells 10 are activated contemporaneously, n is 4 and the summed current is divided by 4 (multiplied by 0.25) as in Equation 3. The accessed data-storing cell 10 (the data-storing cell 10 on Bit Line 30 with an “On” wordline 20) is then compared to I_Reference 110 by the sense amplifier 50 to determine what logical state is stored by the data-storing cell 10. This can then be repeated for the other two possible pairs of adjacent logical states in this example (or some or all of the comparisons can be done simultaneously), i.e., “0” and “2”, and “1” and “2”, to determine the logical state stored by the data-storing cell 10.

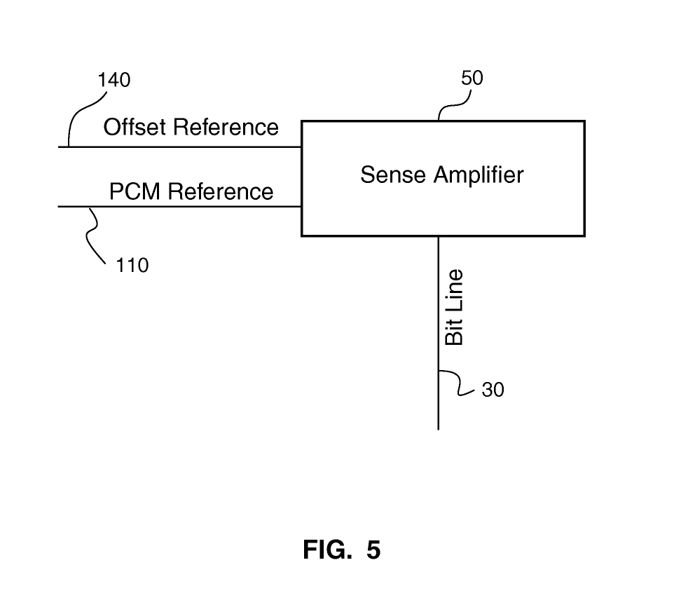

FIG. 5 shows an example of a sense amplifier 50. Here, an Offset Reference 140—a fine trim, generally preset, used to fine-tune the reference, and unsuitable for use by itself as a reference—appears as an additional input to the Sense Amplifier 50, where it will be used to modify the mult-bit PCM Reference 110 generated from reference cells 10 prior to comparison between the data-storing cell 10 output and the reference 110.

FIG. 6A shows an example of a mult-bit PCM memory. In embodiments as shown in FIG. 6A, mult-bit PCM cells 10 are accessed by n wordlines 20 (numbered WL₁ to WLₙ); B data-storing bitlines 30 (numbered BL₁ to BL_{B}), one of which doubles as a reference bitline 30, here BL_{B}; and for k possible states in a particular multi-bit PCM memory, k−1 reference complement bitlines 30 (BLR_{C1} to BLR_{C(k-1)}). Reference cells 10 in the reference complement bitlines 30 BLR_{C1} to BLR_{C(k-1)} store the two or more logical states other than the logical states stored by the corresponding data-storing/reference cells 10 in the dual-purpose data-storing/reference bitline 30 BL_{B}.

In FIG. 6A, a word is accessed by a wordline 20 and bitlines 30 BL₁ to BL_{B}. A mult-bit PCM cell 10 is accessed by activating the corresponding wordline 30 and bitline 20. The data-storing bitlines 30 are sensed by Sense Amplifiers 50 using a reference 110 (I_Reference) generated by a Reference Generator 105. When a word is read by activating a wordline 20—for example, WL₁—and multiple corresponding data-storing bitlines 30, BLR_{C1} to BLR_{C(k-1)} are also activated. The outputs of the data-storing/reference cell 10 activated by WL₁ and BL_{B}, and of the reference complement cells 10 activated by WL₁ and BLR_{C1} to BLR_{C(k-1)}, are used by the Reference Generator to generate references 110 corresponding to each possible pair of adjacent logical states in the multi-bit PCM. The references 110 are then used to read the outputs of the data-storing cells 10 activated by WL₁ and BL₁ through BLₙ.

Also, when a word of data-storing cells 10 corresponding to a wordline WLⱼ are written, the reference complement cells 10 accessed by WLⱼ and BLR_{C1} to BLR_{C(k-1)} are written with the possible logical states other than the logical state stored by the data-storing/reference cell 10 accessed by WLⱼ and BL_{B}, so that the reference complement cells 10 approximately perfectly track the drift characteristics of the corresponding data-storing word.

FIG. 6B shows an example of logical states stored in a multi-bit PCM memory. Multi-bit PCM cells 10 storing logical states (for example, “0”s, “1”s and “2”s) are accessed by corresponding wordlines 20 (WL₁ though WLₙ) and bitlines 30 (BL₁ through BL_{B}), and are interpreted using references 110 generated using outputs of reference cells 10 accessed by a data-storing/reference bitline 30 (BL_{B}) and reference complement bitlines (BLR_{C1} to BLR_{C(k-1)}).

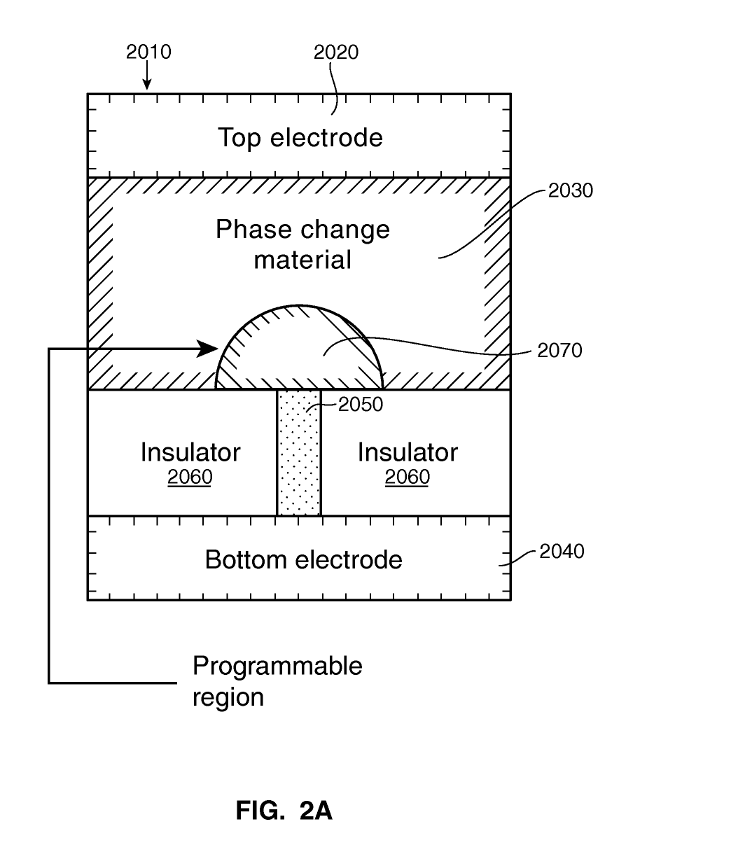

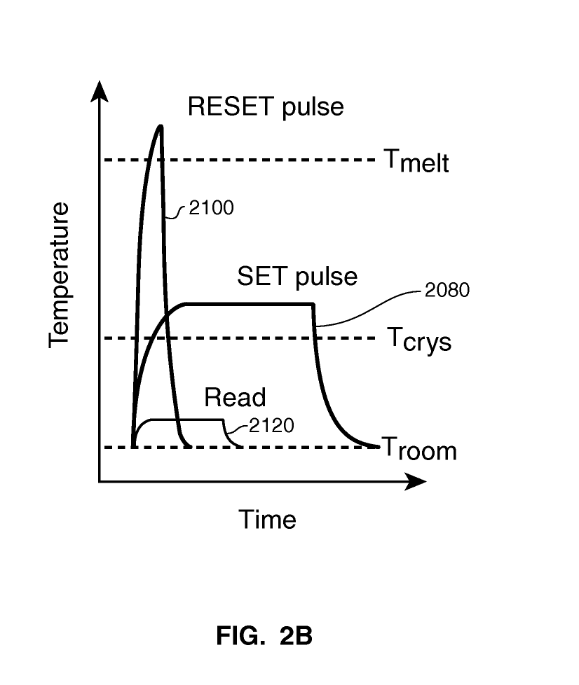

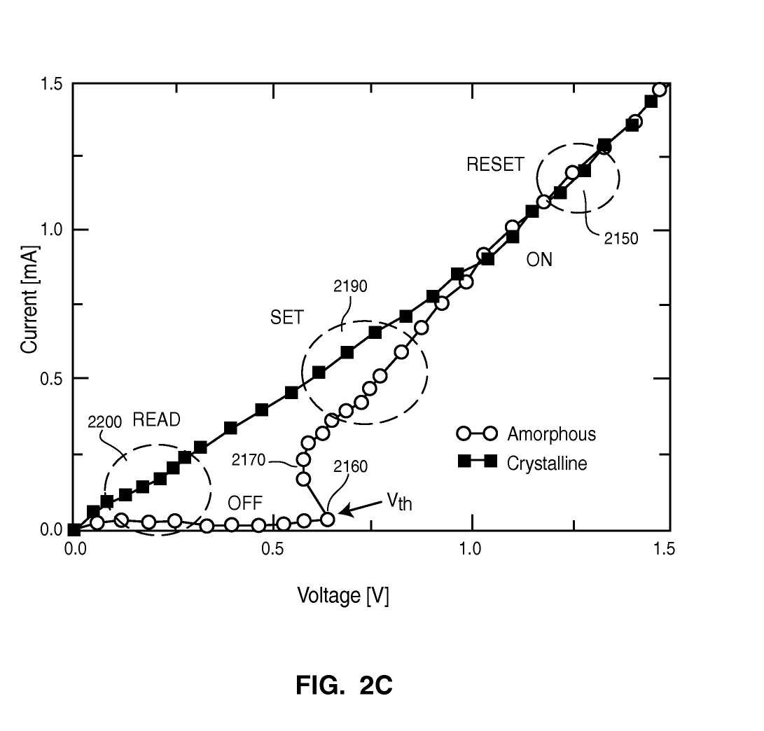

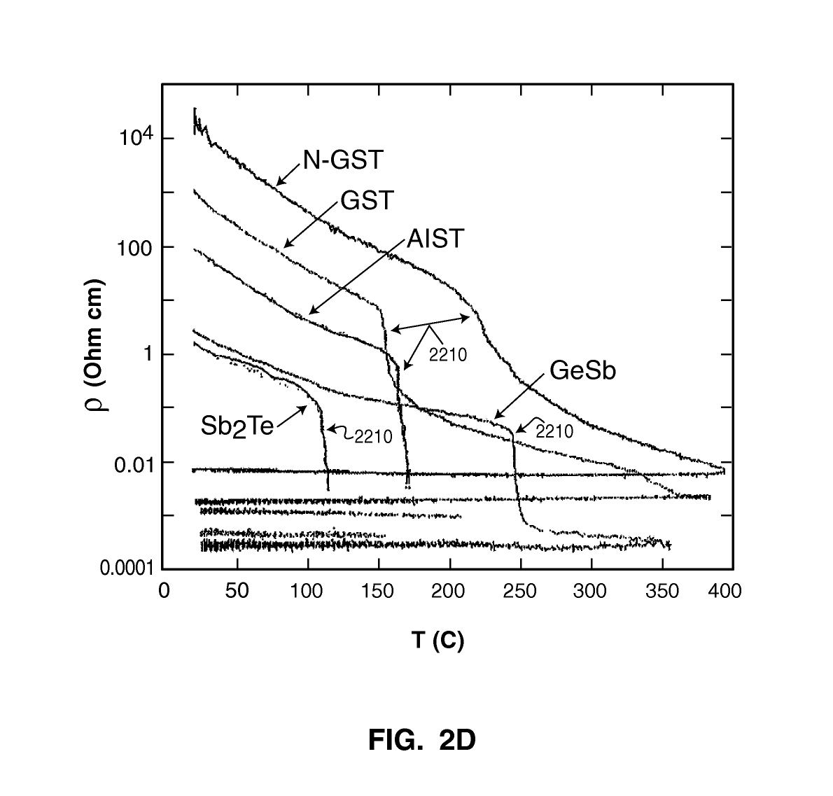

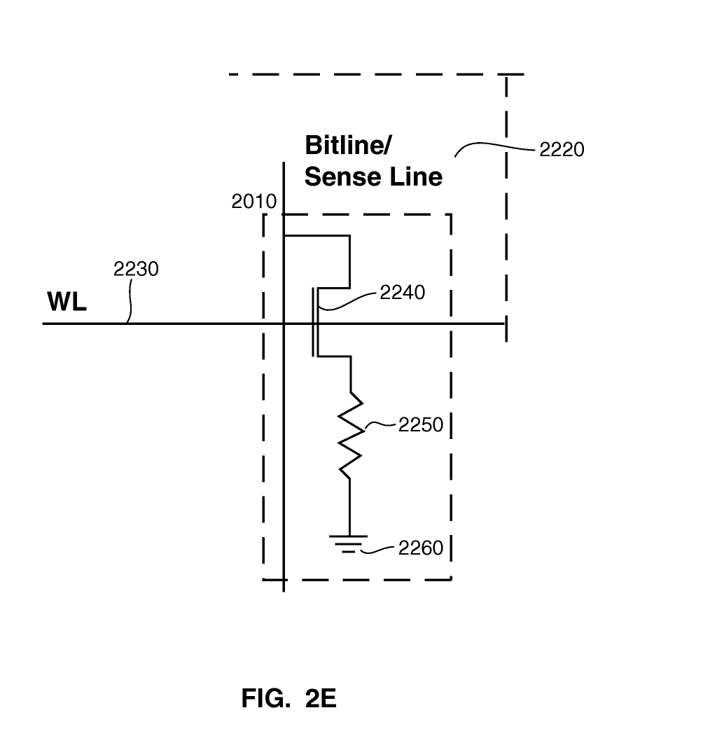

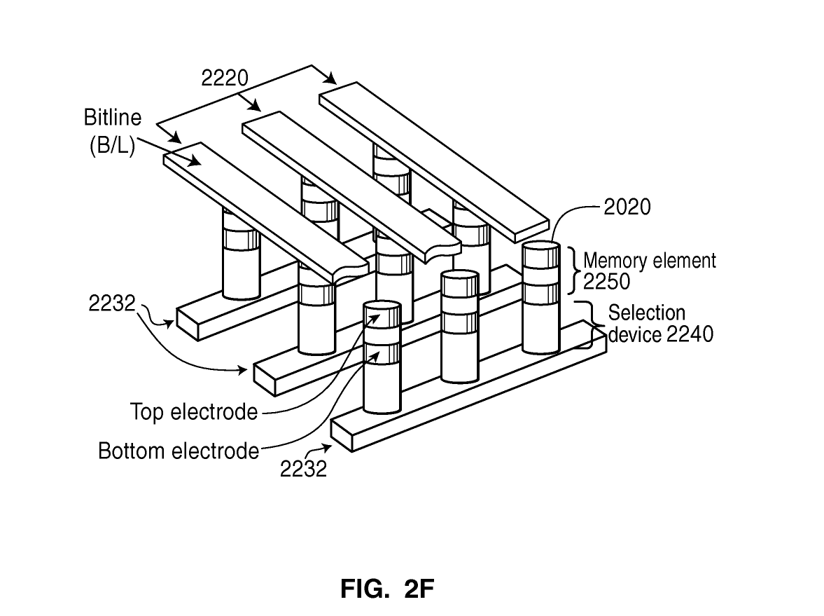

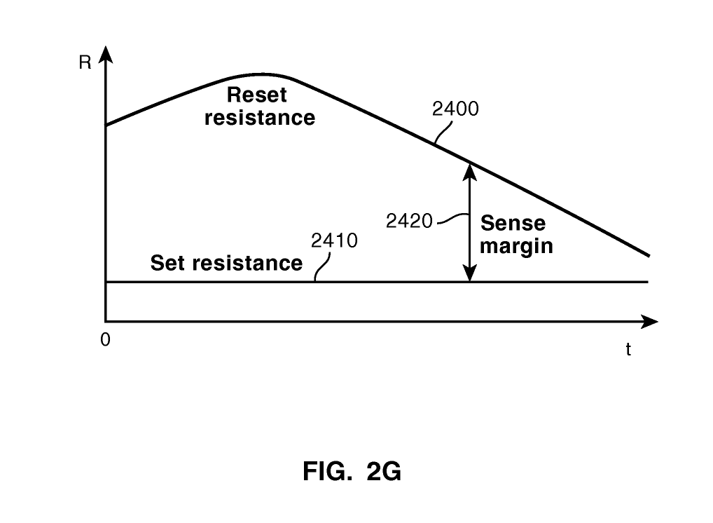

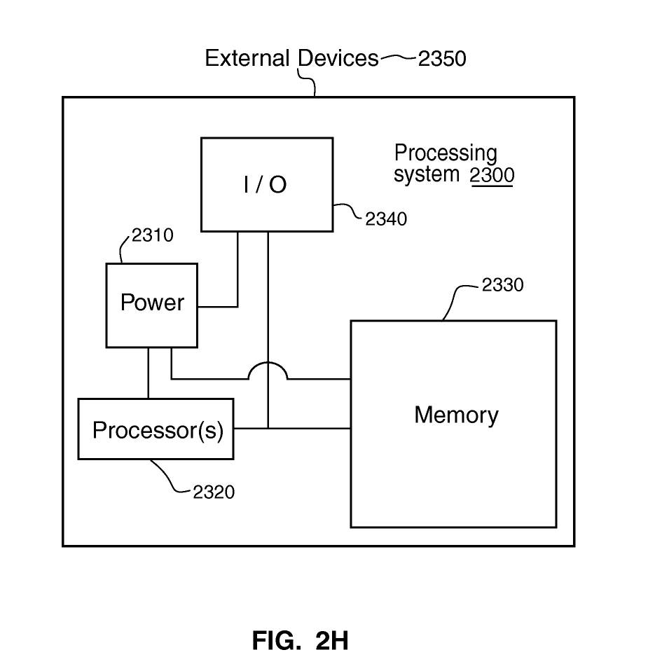

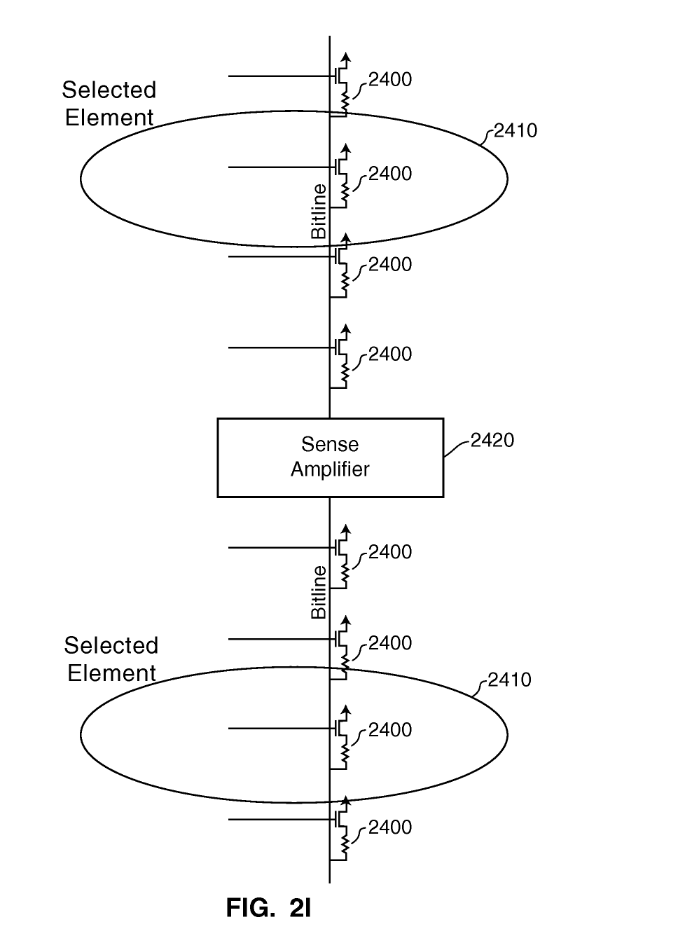

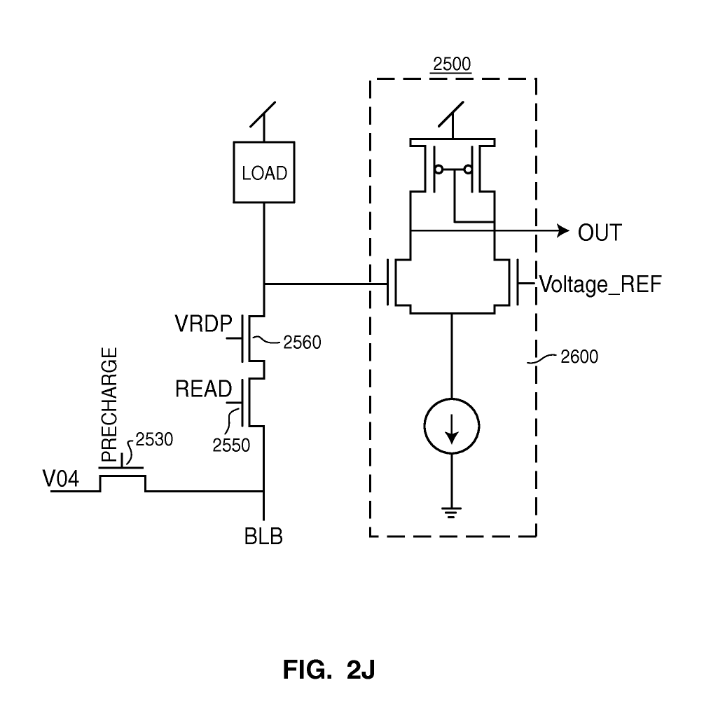

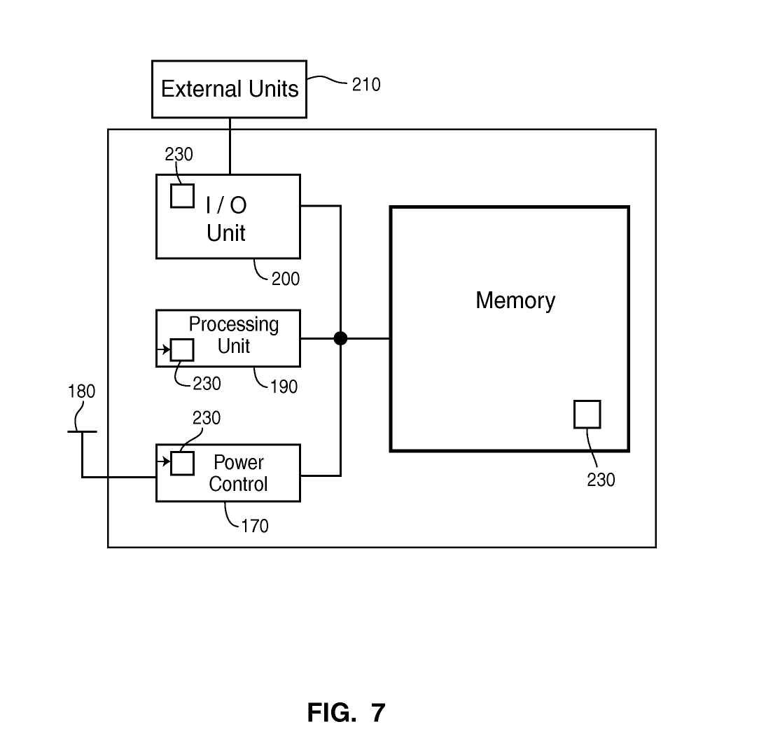

FIG. 7 shows an example of a processing system. Power control 170 manages distribution of power from a power source 180 to other components of the processing system. A processing unit 190 performs processing functions, and an I/O 200 (input/output) unit operates and manages communications with, and enables other processing system components 170, 190, 200, 220 to operate and manage communications with, external units 210. The power control 170, processing unit 190 and I/O unit 200 can also make memory access calls to a memory 220. Processing system components 170, 190, 200, 220 perform their functions based on configuration data stored by non-volatile multi-bit PCM memory 230 integrated into respective processing system components 170, 190, 200, 220. Multi-bit PCM cells 10 in said multi-bit PCM memory 230 are read using references 110 generated as disclosed herein, e.g., with respect to FIGS. 1 through 6.

Configuration data can be loaded into non-volatile memory for runtime accesses. Configuration data can be used to tune multi-bit PCRAM and other component (e.g., power control 170, processing unit 190 or I/O unit 200) behavior in a design, test, or as-manufactured context. Configuration data can comprise, for example, information used by processing system components to operate external units 210; redundancy information, used to redirect accesses (read and write requests) from defective or otherwise inoperative memory cells 10 to redundant (backup) memory cells 10; trim information, generally used to alter the state of an existing topology when device features as-manufactured show variation—which can be expected within some degree of statistical distribution—that can be corrected using measures built into the device; test information used to implement test functions, e.g., for device design, design testing or as-manufactured quality assurance purposes; or to change timing (e.g., sense amp timing, or setup and hold timing in a data path), internal supply voltages, whether ECC (error correction) or other memory or other component functionality is activated, or other component operation parameters (such as word length or instruction set).

In some embodiments, reference cells 10 can be used to store information in the ordering of the corresponding stored logical states. More reference cells 10 storing different logical states can generally store more information. If adjacent logical states stored by reference cells 10 corresponding to a word do not need to be stored with physical or address adjacency, the ordering of said logical states can be used to store an even larger amount of information. Some constraint changes can require a more complex encoder and decoder to properly arrange storage of logical states to both conform to reference cell rules and store increased amounts of information. A pair of reference cells 10 can store, for example, a checksum for a corresponding word; or may store other or additional information.

The amount of information encodeable in reference cells 10 corresponding to a word is proportional to the number of reference cells 10 and the combination of logical states stored by said reference cells 10. For example, the amount of storable information may be different if there are more “1”s than “0”s stored, rather than having an equal number of “1”s and “0”s. Generally, embodiments encoding information using ordering of logical states as stored in reference cells 10 will not segregate a particular logical state to a particular reference bitline (e.g., reference cells 10 accessed by a particular reference bitline will not store only “1”s).

In some embodiments, reference cells 10 can be physically distributed in a memory (e.g., throughout an array); in other embodiments, they may be gathered together (e.g., along bitlines). Preferably, reference cells 10 are located to optimize timing (e.g., voltage rise and hold timing, sense amplifier 50 timing, and read timing in general) and drift matching pursuant to the particular operational characteristics of a multi-bit PCM memory and component architectures thereof such as of sense amplifiers 50.

In some embodiments, after a reference 110 is generated, it is current mirrored and distributed to corresponding sense amplifiers 50.

The disclosed innovations, in various embodiments, provide one or more of at least the following advantages. However, not all of these advantages result from every one of the innovations disclosed, and this list of advantages does not limit the various claimed inventions.

read operation with approximately perfect drift tracking;

no need for coarse trimming;

reduced memory error correction requirements;

more accurate memory reads;

faster memory as a result of a reduced rate of read errors;

denser memory storage from use of mult-bit PCM.

According to some but not necessarily all embodiments, there is provided: A method of operating a memory comprising: when multi-bit phase change memory cells within a word of multi-bit phase change memory cells are written, contemporaneously writing at least one of each possible logical state to a plurality of multi-bit phase change memory reference cells accessed by the same wordline as said word; and when one or more accessed cells in said word is read, using the respective resistances of ones of said reference cells storing adjacent ones of said logical states to provide a reference for said adjacent logical states.

According to some but not necessarily all embodiments, there is provided: A method of operating a memory, comprising: when multi-bit phase change memory cells within a word of multi-bit phase change memory cells are written, contemporaneously writing multiple multi-bit phase change memory reference cells accessed by the same wordline as said word, said reference cells being written with states configured to output, when read, averages of phase change memory read outputs corresponding to pairs of adjacent logical states; and when one or more accessed cells in said word is read, using the respective resistances of ones of said reference cells to provide references for said pairs of adjacent logical states.

According to some but not necessarily all embodiments, there is provided: A memory, comprising: an array of multi-bit phase change memory cells; multiple words of multi-bit phase change memory cells within said array, such that multiple cells within corresponding ones of said words and multiple corresponding multi-bit phase change memory reference cells are configured to be written contemporaneously, said corresponding reference cells being configured to be written with at least one of each possible logical state and to be accessed by the same wordline as said corresponding word; and multiple sense amplifiers configured to read accessed cells in said corresponding word by comparing respective outputs of said accessed cells and multiple references, and by outputting respective logical states of said accessed cells in dependence on said comparing, wherein ones of said references corresponding to pairs of adjacent logical states are generated in at least partial dependence on respective resistances of ones of said corresponding reference cells corresponding to said pairs of adjacent logical states.

According to some but not necessarily all embodiments, there is provided: A memory, comprising: an array of multi-bit phase change memory cells comprising multiple words of data-storing cells and multiple corresponding reference cells configured to be written with at least one of each possible logical state contemporaneously with writes to cells in said corresponding words; multiple word lines, ones of said word lines connected to access rows of said cells, ones of said corresponding words comprising respective portions of said rows of cells accessed by corresponding ones of said word lines; multiple bit lines, ones of said bit lines connected to access columns of said cells; and multiple sense amplifiers configured to read accessed cells in said corresponding word by comparing respective outputs of said accessed cells and multiple references, and by outputting respective logical states of said accessed cells in dependence on said comparing, wherein ones of said references corresponding to pairs of adjacent logical states are generated in at least partial dependence on respective resistances of ones of said corresponding reference cells corresponding to said pairs of adjacent logical states.

According to some but not necessarily all embodiments, there is provided: A memory, comprising: one or more words of multi-bit phase change memory cells, corresponding ones of said words configured to be written contemporaneously with corresponding multi-bit phase change memory reference cells, said corresponding reference cells configured to be written with a state configured to output when read an average of multi-bit phase change memory read outputs corresponding to adjacent complementary logical states; and multiple sense amplifiers configured to read accessed cells in said corresponding word by comparing respective outputs of said accessed cells and multiple references, and by outputting respective logical states of said accessed cells in dependence on said comparing, wherein ones of said references corresponding to pairs of adjacent logical states are generated in at least partial dependence on respective resistances of ones of said corresponding reference cells corresponding to said pairs of adjacent logical states.

According to some but not necessarily all embodiments, there is provided: A method of operating a processing system, comprising: contemporaneously writing multiple cells in corresponding ones of multiple words of multi-bit phase change memory cells and multiple corresponding multi-bit phase change memory reference cells, said words and said reference cells being within a multi-bit phase change memory unit and configured to store configuration data; reading accessed cells in said corresponding word, using multiple sense amplifiers, by comparing respective outputs of said accessed cells and multiple references, and by outputting respective logical states of said accessed cells in dependence on said comparing; and operating external elements, using a processor and/or an input/output unit, in accordance with said configuration data, wherein ones of said references corresponding to pairs of adjacent logical states are generated in at least partial dependence on respective resistances of ones of said corresponding reference cells corresponding to said pairs of adjacent logical states.

According to some but not necessarily all embodiments, there is provided: A processing system, comprising: a multi-bit phase change memory unit, a processor which executes programmable instruction sequences, and an input/output unit; multiple words of multi-bit phase change memory cells within said phase change memory unit configured to store configuration data, multiple cells in corresponding ones of said words and multiple corresponding phase change memory reference cells configured to be written contemporaneously; and multiple sense amplifiers configured to read accessed cells in said corresponding word by comparing respective outputs of said accessed cells and multiple references, and by outputting respective logical states of said accessed cells in dependence on said comparing, wherein ones of said references corresponding to pairs of adjacent logical states are generated in at least partial dependence on respective resistances of ones of said corresponding reference cells corresponding to said pairs of adjacent logical states, and wherein said processor and/or said input/output unit operate external elements in accordance with said configuration data.

According to some but not necessarily all embodiments, there is provided: A method of operating a memory comprising: on at least some occasions when a multi-bit phase change memory cell, which can have any one of n possible states and is gated by a respective wordline, is written, contemporaneously writing at least one of each possible logical state to a respective one of n multi-bit phase change memory reference cells accessed by the same wordline as said word; and when one or more accessed cells in said word is read, using the respective outputs of at least two of said reference cells storing ones of said states which have nearest-neighbor output values to provide a reference for said adjacent states.

According to some but not necessarily all embodiments, there is provided: A method of operating a memory, comprising: on at least some occasions, when multi-bit phase change memory cells within a word of multi-bit phase change memory cells are written, contemporaneously writing multiple multi-bit phase change memory reference cells accessed by the same wordline as said word, said reference cells being written with states configured to output, when read, averages of phase change memory read outputs corresponding to pairs of adjacent logical states; and when one or more accessed cells in said word is read, using the respective outputs of ones of said reference cells to provide references for said pairs of adjacent logical states.

According to some but not necessarily all embodiments, there is provided: Systems and devices in which multi-bit phase change memory is used, including memory systems and memories, as well as methods for operating such systems and devices. According to the present invention, a reference corresponding to a pair of adjacent logical states (e.g., 0 and 1) can be generated by averaging outputs from multiple phase change memory reference cells designated to store said adjacent logical states. By writing reference cells contemporaneously with words of cells that are configured to be written together, resulting references can closely track output changes in corresponding ones of said words resulting from, e.g., drift and other time- and phase change material-dependent factors. Ordering of states within said reference cells can be used to encode information such as checksums of corresponding words.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

In some embodiments, ones of one or more words in an array of multi-bit PCM cells correspond to multiple groups of multi-bit PCM reference cells.

In some embodiments, one or more groups of multi-bit PCM reference cells storing the possible states stored by a multi-bit PCM memory correspond to (are shared by) multiple words. In such embodiments, it is preferable to write said multiple words as closely to contemporaneously as possible in order to match drift characteristics of cells in said multiple words to drift characteristics of said shared reference cells as closely as possible. This can be useful, for example, when a substantial segment—or entirety—of a multi-bit PCM array is being written together, such as during testing.

In some embodiments, a group of multi-bit PCM reference cells contains more reference cells than the number of possible logical states. This can be used to, for example, enhance reliability and accuracy of the resulting reference generated from the multi-bit reference cells.

In some embodiments, reference cells can be read differentially, i.e., by comparing a read output of a reference cell to a read output of another multi-bit PCM cell. This can be used, for example, to enhance read reliability of the reference cell.

In some embodiments, multi-bit PCM reference cells are not grouped with only one of each logical state stored per group, e.g., there can be more “1” states stored than “2” states in a group of reference cells. This can be used to save memory area where, for example, outputs of low resistance cells are significantly more reliable (e.g., more consistent output) than outputs of high resistance cells (or vice versa).

In some embodiments, a higher output current represents a lower numbered state, and a lower output current represents a higher numbered state.

Embodiments have been disclosed hereinabove with particular numbers and configurations of wordlines, bitlines, sense amplifiers, muxes, data-storing cells, reference cells and other features. However, it will be apparent to one of ordinary skill that different arrangements of such features may be used to implement the inventions disclosed herein.

In some embodiments, bitline contents may not be strictly divided into data-storage bitlines and reference bitlines.

In some embodiments, a weighted arithmetic mean, geometric mean, or other operation producing a reference obeying the inequality described above, Ipcm0<I_Reference<Ipcm1, may be used to generate a reference (these means and other operations are referred to as “averages” for this purpose).

In some embodiments, all or substantially all cells in a word are configured to be written contemporaneously.

In some embodiments, all or substantially all cells in a word are configured to be read contemporaneously.

In some embodiments, multi-bit SET and RESET pulses can be configured to reset multi-bit PCM cell drift characteristics of multi-bit PCM cells without requiring a logical state change or transposition to reset cell drift characteristics.

In some embodiments, a state change or transposition can be used to reset multi-bit PCM cell drift characteristics.

In some embodiments, resistance values configured to produce read outputs corresponding to those of multi-bit PCM cells storing adjacent logical states with a pre-determined drift amount (e.g., no drift) are hard-coded, e.g., in resistance trims, in a multi-bit PCM memory. When a corresponding word of multi-bit PCM cells is written, the resistance trims are read, and a state configured to produce a read output corresponding to an average of the resistance trims' read outputs is written into one or more corresponding PCM reference cells. This is performed (corresponding resistance trims having been hard coded) for each possible pair of adjacent logical states for the states storable by the particular multi-bit PCM memory. When the corresponding word is read, the corresponding PCM reference cells are read. If there is only one corresponding reference cell for the corresponding word, the corresponding reference cell's output is used as the reference for the corresponding word. If there are multiple corresponding reference cells, then their summed outputs are divided by the number of corresponding reference cells (or by another value resulting in a reference obeying the constraints described herein for I_Reference), and the resulting current is used as the reference for the corresponding word. In some embodiments, multiple resistance trims are hard-coded with resistances configured to output on read the average of read outputs of multi-bit PCM cells storing adjacent logical states—at least enough resistance trims to provide a different reference for each possible pair of adjacent logical states storable by the multi-bit PCM cells.

Additional general background, which helps to show variations and implementations, may be found in the following publications, all of which are hereby incorporated by reference: Lam, Chung. “Phase Change Memory: A Replacement or Transformational Memory Technology,” IEEE Workshop on Microelectronics and Electron Devices (WMED), c. 2011. Choi, Youngdon, et al. “A 20 nm 1.8V 8 Gb PRAM with 40 MB/s Program Bandwidth.” ISSCC 2012/Session 2/High Bandwidth DRAM & PRAM/2.5. c. 2012.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

Additional general background, which helps to show variations and implementations, as well as some features which can be synergistically with the inventions claimed below, may be found in the following US patent applications. All of these applications have at least some common ownership, copendency, and inventorship with the present application, and all of them are hereby incorporated by reference: US Provisional Pat. Nos. 61/637,331; 61/637,496; 61/637,513; 61/637,518; 61/637,526; 61/637,533; 61/638,217; 61/694,217; 61/694,220; 61/694,221; 61/694,223; 61/694,224; 61/694,225; 61/694,228; 61/694,234; 61/694,240; 61/694,242; 61/694,243; and 61/694,245.

The claims as filed are intended to be as comprehensive as possible, and NO subject matter is intentionally relinquished, dedicated, or abandoned.

What is claimed is:

1. A method of operating a processing system, comprising:
contemporaneously writing multiple cells in corresponding ones of multiple words of multi-bit phase change memory cells and multiple corresponding multi-bit phase change memory reference cells, said words and said reference cells being within a multi-bit phase change memory unit and configured to store configuration data;
reading accessed cells in said corresponding word, using multiple sense amplifiers, by comparing respective outputs of said accessed cells and multiple references, and by outputting respective logical states of said accessed cells in dependence on said comparing; and
operating external elements, using a processor and/or an input/output unit, in accordance with said configuration data,
wherein ones of said references corresponding to pairs of adjacent logical states are generated in at least partial dependence on respective outputs of ones of said corresponding reference cells corresponding to said pairs of adjacent logical states.

2. The method of operating a processing system of claim 1, wherein said configuration data is read from said phase change memory unit and loaded into volatile memory prior to said external elements being operated in accordance with said configuration data by said processor and/or said input/output unit.

3. The method of operating a processing system of claim 1, wherein said configuration data is read from said phase change memory unit and loaded into volatile memory prior to said external elements being operated in accordance with said configuration data by said processor.

4. The method of operating a processing system of claim 1, wherein said configuration data is read from said phase change memory unit and loaded into volatile memory prior to said external elements being operated in accordance with said configuration data by said input/output unit.

5. The method of operating a processing system of claim 1, wherein said respective outputs of said reference cells are used to provide a reference for each possible pair of adjacent logical states.

6. The method of operating a processing system of claim 1, wherein the ordering of logical states within said reference cells encodes a checksum of said word.

7. The method of operating a processing system of claim 1, wherein said reference is an average of read outputs corresponding to said adjacent logical states.

8. The method of operating a processing system of claim 1, wherein reference cells are not required to change phase state when written.

9. The method of operating a processing system of claim 1, wherein an ordering of logical states written to said reference cells encodes information.

10. The method of operating a processing system of claim 1, wherein said writing said reference cells comprises generating averages of read outputs corresponding to pairs of adjacent logical states and writing to said reference cells states configured to output said averages when said reference cells are read.

11. A processing system, comprising:
a multi-bit phase change memory unit, a processor which executes programmable instruction sequences, and an input/output unit;
multiple words of multi-bit phase change memory cells within said phase change memory unit configured to store configuration data, multiple cells in corresponding ones of said words and multiple corresponding phase change memory reference cells configured to be written contemporaneously; and
multiple sense amplifiers configured to read accessed cells in said corresponding word by comparing respective outputs of said accessed cells and multiple references, and by outputting respective logical states of said accessed cells in dependence on said comparing,
wherein ones of said references corresponding to pairs of adjacent logical states are generated in at least partial dependence on respective outputs of ones of said corresponding reference cells corresponding to said pairs of adjacent logical states, and
wherein said processor and/or said input/output unit operate external elements in accordance with said configuration data.

12. The method of operating a processing system of claim 11, wherein said configuration data is read from said phase change memory unit and loaded into volatile memory prior to said external elements being operated in accordance with said configuration data by said processor and/or said input/output unit.

13. The method of operating a processing system of claim 11, wherein said configuration data is read from said phase change memory unit and loaded into volatile memory prior to said external elements being operated in accordance with said configuration data by said processor.

14. The method of operating a processing system of claim 11, wherein said configuration data is read from said phase change memory unit and loaded into volatile memory prior to said external elements being operated in accordance with said configuration data by said input/output unit.

15. The method of operating a processing system of claim 11, wherein said respective outputs of said reference cells are used to provide a reference for each possible pair of adjacent logical states.

16. The method of operating a processing system of claim 11, wherein the ordering of logical states within said reference cells encodes a checksum of said word.

17. The method of operating a processing system of claim 11, wherein said reference is an average of read outputs corresponding to said adjacent logical states.

18. The method of operating a processing system of claim 11, wherein reference cells are not required to change phase state when written.

19. The method of operating a processing system of claim 11, wherein an ordering of logical states written to said reference cells encodes information.

20. The method of operating a processing system of claim 11, wherein said writing said reference cells comprises generating averages of read outputs corresponding to pairs of adjacent logical states and writing to said reference cells states configured to output said averages when said reference cells are read.
